(19) United States
(12) Patent Application Publication
(10) Pub. No.: US 2026/0282825 A1
(43) Pub. Date: Sep. 17, 2026

(54) SUBSTRATE PROCESSING SYSTEM, SUBSTRATE PROCESSING METHOD, AND NON-TRANSITORY COMPUTER-READABLE STORAGE MEDIUM

(71) Applicant: Tokyo Electron Limited, Tokyo (JP)

(72) Inventors: Hideto SAITO, Miyagi (JP); Joji TAKAYOSHI, Miyagi (JP); Yuta KINOKUNI, Miyagi (JP); Hidehiko SATO, Miyagi (JP); Ryohei TAKEDA, Miyagi (JP); Kyuri MOTOKAWA, Miyagi (JP); Muneyuki OMI, Miyagi (JP)

(73) Assignee: Tokyo Electron Limited, Tokyo (JP)

(21) Appl. No.: 19/466,579

(22) Filed: Feb. 2, 2026

Related U.S. Application Data
(63) Continuation of application No. PCT/JP2024/027186, filed on Jul. 30, 2024.

(30) Foreign Application Priority Data
Aug. 10, 2023 (JP) 2023-131034

(51) Int. Cl. H10P 72/50; H01J 37/32; H10P 72/72; H10P 72/76

(52) U.S. Cl. CPC H10P 72/53; H01J 37/32715; H01J 37/32743; H10P 72/722; H10P 72/7602; H01J 2237/2007; H01J 2237/24578

(57) ABSTRACT

A substrate processing system includes a process module having a chamber and a substrate support disposed in the chamber and performing substrate processing, a transfer module including a transfer robot, a camera having a field of view including a transfer path of the substrate, the camera acquiring an image of the substrate, processing circuitry including a detector detecting a first characteristic pattern having a center that reflects a center position of the substrate, and a second characteristic pattern having a center that reflects a center position of the substrate support during the substrate processing and a calculator calculating a positional relationship between a position of the substrate support and a position of the substrate during the substrate processing, based on the first characteristic pattern and the second characteristic pattern, and transfer controller circuitry correcting the transfer position for the transfer module based on the positional relationship.

### CROSS-REFERENCE TO RELATED APPLICATIONS

This application is a continuation application of PCT Application No. PCT/JP2024/027186, filed on Jul. 30, 2024, which claims the benefit of priority from Japanese Patent Application No. 2023-131034, filed on Aug. 10, 2023. The entire contents of the above listed PCT and priority applications are incorporated herein by reference.

### BACKGROUND

### Field

Example embodiments of the present disclosure relate to a substrate processing system, a substrate processing method, and a non-transitory computer-readable storage medium.

### Description of the Related Art

A substrate processing system is used in processing for a substrate. A substrate processing system disclosed in Japanese Unexamined Patent Application Publication No. 2003-264214 discloses a process module and a transfer module. The process module includes a chamber, and a substrate support disposed in the chamber. The transfer module transfers a substrate onto the substrate support. In the process module, substrate processing is performed on the substrate transferred onto the substrate support.

### SUMMARY

The present disclosure provides a technology for reducing a deviation of a transfer position of a substrate with respect to a substrate support.

In one example embodiment, a substrate processing system is provided. The substrate processing system includes a process module, a transfer module, a camera, processing circuitry including a detector and a calculator, and a transfer controller circuitry. The process module has a chamber and a substrate support disposed in the chamber. The process module performs substrate processing on a substrate on the substrate support. The transfer module includes a transfer robot transferring a substrate to a transfer position on the substrate support. The camera has a field of view including a transfer path of the substrate. The camera acquires an image of the substrate. The detector is configured to detect a first characteristic pattern and a second characteristic pattern from an image of the substrate on which substrate processing has been performed. The first characteristic pattern has a center that reflects a center position of the substrate. The second characteristic pattern has a center that reflects a center position of the substrate support during the substrate processing. The calculator is configured to calculate a positional relationship between a position of the substrate support and a position of the substrate during the substrate processing, based on the first characteristic pattern and the second characteristic pattern. The transfer controller circuitry is configured to correct the transfer position for the transfer module based on the positional relationship.

### BRIEF DESCRIPTION OF THE DRAWINGS

FIG. 1 is a diagram showing a substrate processing system according to one example embodiment.

FIG. 2 is a diagram for describing a configuration example of a plasma substrate processing system.

FIG. 3 is a diagram for describing a configuration example of a capacitively coupled plasma processing apparatus.

FIG. 4 is a top view of an electrostatic chuck according to one example embodiment.

FIG. 5 is a partially enlarged view of one example embodiment of the electrostatic chuck shown in FIG. 4.

FIG. 6 is a partially enlarged cross-sectional view of a substrate and an electrostatic chuck according to one example embodiment.

FIG. 7 is a cross-sectional view of a substrate inspection module according to one example embodiment.

FIG. 8 is a diagram schematically showing an image of a substrate according to one example embodiment on which substrate processing has been performed.

FIG. 9 is a diagram schematically showing an image of a substrate according to another example embodiment on which substrate processing has been performed.

FIG. 10 is a diagram schematically showing an image of a substrate according to still another example embodiment on which substrate processing has been performed.

FIG. 11 is a diagram showing one example embodiment showing a positional relationship between a center position of a substrate and a center position of a substrate support during substrate processing.

FIG. 12 is a diagram showing a configuration of an imaging unit according to another example embodiment.

FIG. 13 is a diagram schematically showing an image of a substrate according to still another example embodiment on which substrate processing has been performed.

FIG. 14 is a diagram showing an example of a process of calculating a positional relationship between a position of a substrate and a position of a pattern.

FIG. 15 is a diagram showing another example of a process of calculating a positional relationship between a position of a substrate and a position of a pattern.

FIG. 16 is a flowchart describing a substrate processing method according to one example embodiment.

### DETAILED DESCRIPTION

Hereinafter, various example embodiments will be described in detail with reference to the drawings. In the drawings, the same reference numerals are assigned to the same or corresponding parts.

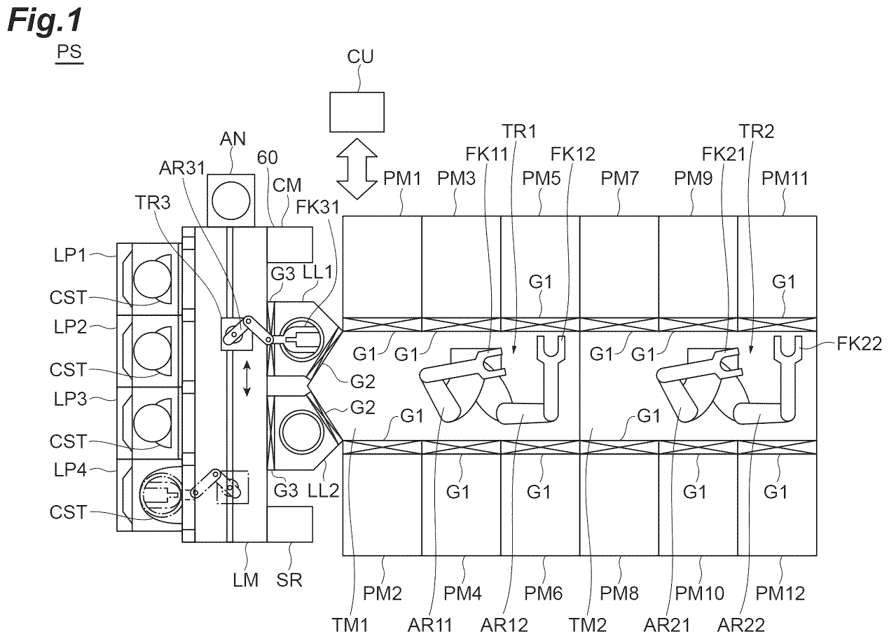

FIG. 1 is a diagram showing a substrate processing system according to one example embodiment. As shown in FIG. 1, a substrate processing system PS includes at least one transfer module, at least one process module, an imaging unit 60 (i.e., camera), and a transfer controller CU (i.e., transfer controller circuitry). The substrate processing system PS may include a plurality of process modules PM1 to PM12 as the at least one process module, and may include a plurality of transfer modules TM1, TM2 as the at least one transfer module. The substrate processing system PS may further include a substrate inspection module CM, load ports LP1 to LP4, an aligner AN, load lock modules LL1, LL2, and a storage SR.

The substrate processing system PS may further include a loader module LM. The loader module LM includes a chamber. The pressure in the chamber of the loader module LM is set to atmospheric pressure. The loader module LM may have an FFU (Fan Filter Unit). The loader module LM is, for example, an EFEM (Equipment Front End Module). The loader module LM is disposed between each of the load ports LP1 to LP4 and each of the load lock modules LL1, LL2. The load ports LP1 to LP4 are arranged along one of a pair of edges along a longitudinal direction of the loader module LM. The load lock modules LL1, LL2 are arranged along the other of the pair of edges along the longitudinal direction of the loader module LM. Each of the load ports LP1 to LP4 is configured to support a cassette CST placed thereon. The cassette CST is a container that accommodates a plurality of substrates W therein. The cassette CST is, for example, a FOUP (Front-Opening Unified Pod).

The loader module LM includes a transfer robot TR3. The transfer robot TR3 is provided in the chamber of the loader module LM. The transfer robot TR3 may include a multi-joint arm AR31 and a pick (end effector) FK31. The pick FK31 is attached to a tip of the multi-joint arm AR31 and is configured to support a substrate W placed thereon. The transfer robot TR3 transfers the substrate W based on an operation instruction output from a transfer controller CU, which will be described later. The transfer robot TR3 transfers the substrate W between any two of a cassette CST placed on at least one of the load ports LP1 to LP4, the load lock modules LL1, LL2, the aligner AN, the storage SR, and a substrate inspection module CM to be described later.

The aligner AN is disposed along one of a pair of edges along a short-side direction of the loader module LM. The aligner AN may be disposed along an edge along the longitudinal direction of the loader module LM. Further, the aligner AN may be disposed in the chamber of the loader module LM. The aligner AN has a support stage, an optical sensor, and the like. The support stage of the aligner AN is rotatable and supports a substrate W placed thereon. The aligner AN detects an angular position of a marker (for example, a notch) of the substrate W on the support stage and a center position of the substrate W on the support stage using the optical sensor. The transfer controller CU controls rotation of the support stage of the aligner AN so as to correct the angular position of the marker (for example, a notch) of the substrate W on the support stage to a reference angular position, so as to correct an amount of deviation of the angular position of the substrate W. Further, the transfer controller CU controls a position of the pick FK31 when receiving the substrate W from the aligner AN onto the pick FK31 in order to position the center of the substrate W on a predetermined position of the pick FK31.

The storage SR is disposed along an edge along the longitudinal direction of the loader module LM. The storage SR may be disposed along an edge along the short-side direction of the loader module LM. Further, the storage SR may be provided inside the loader module LM. The storage SR is configured to accommodate the substrate W therein.

The substrate inspection module CM is disposed along an edge along the longitudinal direction of the loader module LM. The substrate inspection module CM may be disposed along an edge along the short-side direction of the loader module LM. Further, the substrate inspection module CM may be provided inside the loader module LM. In the example illustrated in FIG. 1, the imaging unit 60 is included in the substrate inspection module CM. The substrate inspection module CM is configured to perform an image inspection on the substrate W. Details of the substrate inspection module CM will be described later.

Each of the load lock modules LL1, LL2 is disposed between the transfer module TM1 and the loader module LM. Each of the load lock modules LL1, LL2 provides a preliminary vacuum chamber. Each of the load lock modules LL1, LL2 and the loader module LM are connected via a gate valve G3. Each of the load lock modules LL1, LL2 and the transfer module TM1 are connected via a gate valve G2.

In one embodiment, each of the transfer modules TM1, TM2 may include a chamber. In the example illustrated in FIG. 1, each of the transfer modules TM1, TM2 is configured to transfer the substrate W through a decompressed space in its chamber. The chamber of the transfer module TM1 is connected to each of the load lock modules LL1, LL2 via the gate valve G2. Process modules PM1 to PM6 are connected to the chamber of the transfer module TM1 via a gate valve G1. The chamber of the transfer module TM1 is connected to a chamber of the transfer module TM2. Process modules PM7 to PM12 are connected to the chamber of the transfer module TM2 via the gate valve G1.

In one embodiment, the transfer module TM1 may include a transfer robot TR1 provided in its chamber. The transfer robot TR1 may include multi-joint arms AR11, AR12 and picks (i.e., end effectors) FK11, FK12. The pick FK11 is attached to a tip of the multi-joint arm AR11 and is configured to support a substrate W placed thereon. The pick FK12 is attached to a tip of the multi-joint arm AR12 and is configured to support a substrate W placed thereon. The transfer robot TR1 transfers the substrate W based on an operation instruction output from a transfer controller CU to be described later. The transfer robot TR1 holds the substrate W by the picks FK11, FK12. The transfer robot TR1 transfers the substrate W between any two of the load lock modules LL1, LL2, the process modules PM1 to PM6, the chamber of the transfer module TM1, and a path between the chamber of the transfer module TM1 and the chamber of TM2.

In one embodiment, the transfer module TM2 includes a transfer robot TR2 provided in its chamber. The transfer robot TR2 may include multi-joint arms AR21, AR22 and picks (i.e., end effectors) FK21, FK22. The pick FK21 is attached to a tip of the multi-joint arm AR21 and is configured to support a substrate W placed thereon. The pick FK22 is attached to a tip of the multi-joint arm AR22 and is configured to support a substrate W placed thereon. The transfer robot TR2 transfers the substrate W based on an operation instruction output from a transfer controller CU to be described later. The transfer robot TR2 holds the substrate W by the picks FK21, FK22. The transfer robot TR2 transfers the substrate W between any two of a path between the chamber of the transfer module TM1 and the chamber of the transfer module TM2, the process modules PM7 to PM12, and the chamber of the transfer module TM2.

In one embodiment, each of the process modules PM1 to PM12 is configured to perform a dedicated process on the substrate W. At least one of the process modules PM1 to PM12 is a substrate processing system such as a plasma processing apparatus 1 to be described later.

The transfer controller CU is, for example, a computer. The transfer controller CU may be configured with a CPU (Central Processing Unit), a RAM (Random Access Memory), a ROM (Read Only Memory), an auxiliary storage device, and the like. The CPU operates based on a program stored in the ROM or the auxiliary storage device and controls each part of the substrate processing system PS.

Note that the substrate processing system PS is not necessarily limited to that illustrated in FIG. 1. For example, the number of process modules and/or the number of transfer modules in the substrate processing system may be different from those illustrated in FIG. 1. For example, the number of load ports may be five or more, and the number of load ports may be any number. Further, the substrate processing system may be a system in which a plurality of module groups, each including a process module and a load lock module, are connected to a loader module (a so-called loader type system). Further, the substrate processing system may be a system in which two or more process modules are arranged and connected around a transfer module so as to surround the transfer module (a so-called cluster type system).

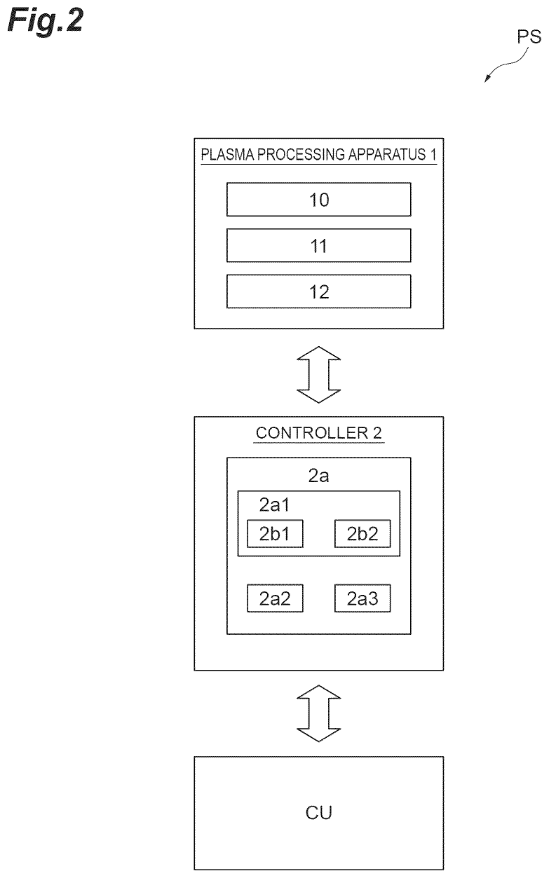

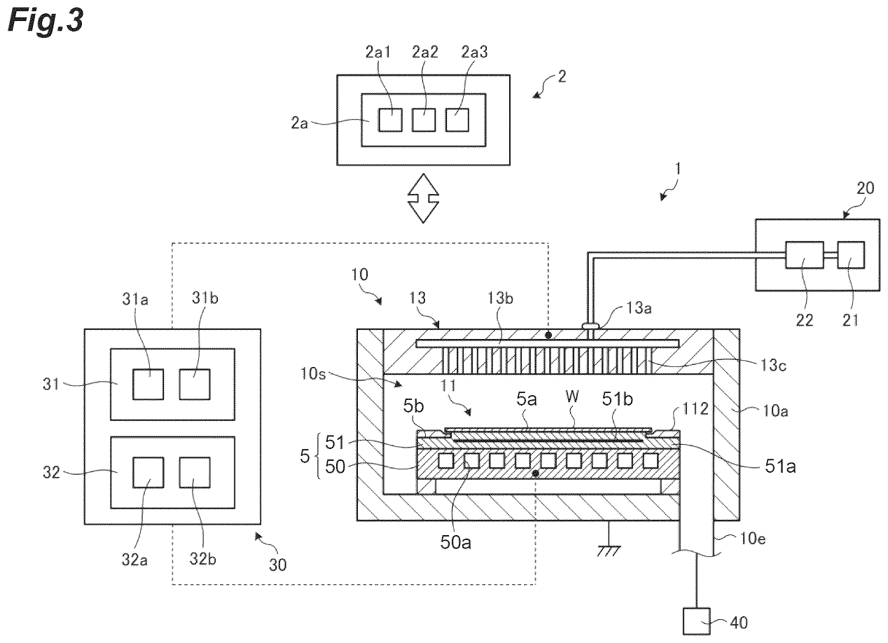

Hereinafter, reference is made to FIG. 2 and FIG. 3. The plasma processing system illustrated in FIG. 2 is an example of the substrate processing system PS. An example of the plasma processing apparatus illustrated in FIG. 3 is adopted as at least one process module among the process modules PM1 to 12.

FIG. 2 describes an example configuration of a plasma processing system. In an embodiment, the plasma processing system includes a plasma processing apparatus 1 and a controller 2. The plasma processing system is an example substrate processing system, and the plasma processing apparatus 1 is an example substrate processing system. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate support surface 11a for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2al, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

The substrate processing system PS includes a detector 2b1 and a calculator 2b2. In the example illustrated in FIG. 2, the detector 2b1 and the calculator 2b2 are included in a processor 2al. Details of the detector 2b1 and the calculator 2b2 will be described later. The detector 2b1 and the calculator 2b2 may be included in the transfer controller CU. The controller 2 may also serve as the transfer controller CU.

An example configuration of a capacitively coupled plasma processing apparatus, which is an example of the plasma processing apparatus 1, will now be described. FIG. 3 describes the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 5 and a ring assembly 112. The body 5 has a central region 5a for supporting a substrate W and an annular region 5b for supporting the ring assembly 112. An example of the substrate W is a wafer. The annular region 5b of the body 5 surrounds the central region 5a of the body 5 in plan view. The substrate W is disposed on the central region 5a of the body 5, and the ring assembly 112 is disposed on the annular region 5b of the body 5 so as to surround the substrate W on the central region 5a of the body 5. Thus, the central region 5a is also called a substrate supporting surface for supporting the substrate W, while the annular region 5b is also called a ring supporting surface for supporting the ring assembly 112.

In an embodiment, the body 5 includes a base 50 and an electrostatic chuck 51. The base 50 includes a conductive member. The conductive member of the base 50 can function as a lower electrode. The electrostatic chuck 51 is disposed on the base 50. The electrostatic chuck 51 includes a ceramic member 51a and an electrostatic electrode 51b disposed in the ceramic member 51a. The ceramic member 51a has the central region 5a. In an embodiment, the ceramic member 51a also has the annular region 5b. Any other member, such as an annular electrostatic chuck or an annular insulting member, surrounding the electrostatic chuck 51 may have the annular region 5b. In this case, the ring assembly 112 may be disposed on either the annular electrostatic chuck or the annular insulating member, or both the electrostatic chuck 51 and the annular insulating member. At least one RF/DC electrode coupled to an RF source 31 and/or a DC source 32 described below may be disposed in the ceramic member 51a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 50 and the at least one RF/DC electrode may each function as a lower electrode. The electrostatic electrode 51b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 51, the ring assembly 112, and the substrate to a target temperature. The temperature adjusting module may be a heater, a heat transfer medium, a flow passage 50a, or any combination thereof. A heat transfer fluid, such as brine or gas, flows into the flow passage 50a. In an embodiment, the flow passage 50a is formed in the base 50, one or more heaters are disposed in the ceramic member 51a of the electrostatic chuck 51. The substrate support 11 may further include a heat transfer gas supply configured to supply a heat transfer gas to a gap between the rear surface of the substrate W and the central region 5a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

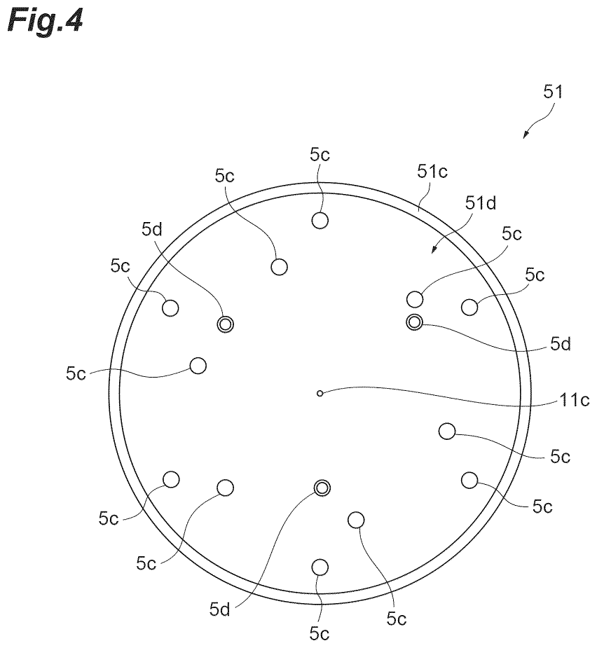

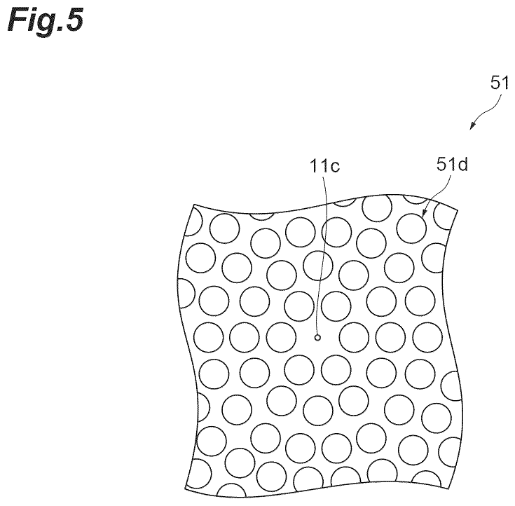

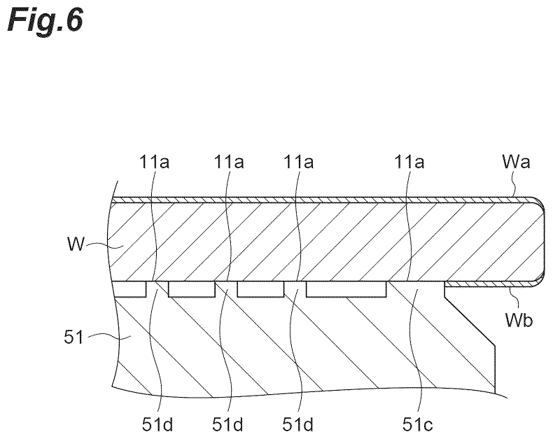

Hereinafter, reference is made to FIG. 4 to FIG. 6. FIG. 4 is a top view of an electrostatic chuck according to one example embodiment. FIG. 5 is a partially enlarged view of one example embodiment of the electrostatic chuck illustrated in FIG. 4. FIG. 6 is a partially enlarged cross-sectional view of a substrate and an electrostatic chuck according to one example embodiment.

In one embodiment, the electrostatic chuck 51 may include a first protrusion 51c (or a seal ring) and a plurality of second protrusions 51d (or dot portions). The first protrusion 51c and the plurality of second protrusions 51d are included in a surface structure of the electrostatic chuck 51. The first protrusion 51c has an annular shape. The first protrusion 51c has an upper surface that forms a part of the substrate support surface 11a. As illustrated in FIG. 4 to FIG. 6, the first protrusion 51c may have an annular shape along an outer edge of the substrate support surface 11a. In this case, a pattern of the first protrusion 51c is an annular shape along the outer edge of the substrate support surface 11a.

Each of the plurality of second protrusions 51d has an upper surface that forms a part of the substrate support surface 11a. The plurality of second protrusions 51d are disposed inside the first protrusion 51c. In the example shown in FIG. 4, the plurality of second protrusions 51d are disposed inside an outer edge of the substrate support surface 11a. Each of the plurality of second protrusions 51d is not shown in FIG. 4. As shown in FIG. 5, the plurality of second protrusions 51d may form a pattern centered on a center position 11c of the substrate support 11. In the example shown in FIG. 5, the plurality of second protrusions 51d are arranged at approximately equal intervals along a circumference centered on the center position 11c of the substrate support 11. The plurality of second protrusions 51d may be arranged along a plurality of concentric circles centered on the center position 11c of the substrate support 11, or may be arranged along a plurality of concentric polygons centered on the center position 11c of the substrate support 11.

In one embodiment, the substrate support 11 may include a plurality of gas holes 5c. The plurality of gas holes 5c are included in the surface structure of the electrostatic chuck 51. In the example illustrated in FIG. 4, the plurality of gas holes 5c are composed of twelve gas holes 5c. The plurality of gas holes 5c communicate with a gap between the substrate W and the electrostatic chuck 51. The gap between the substrate W and the electrostatic chuck 51 corresponds to the gap between a lower surface of the substrate W and the central region 5a described above. In one example, each of the plurality of gas holes 5c is composed of a through-hole of the electrostatic chuck 51 and a through-hole of the base 50 that communicate with each other. The heat transfer gas supply unit may be configured to supply a heat transfer gas to the gap between the substrate W and the electrostatic chuck 51 through the plurality of gas holes 5c.

As illustrated in FIG. 4, the plurality of gas holes 5c may form a pattern centered on the center position 11c of the substrate support 11. In the example illustrated in FIG. 4, the plurality of gas holes 5c are disposed at vertices of a hexagon centered on the center position 11c of the substrate support 11. In this case, the pattern of the plurality of gas holes 5c includes a hexagon. More specifically, six of the twelve gas holes 5c are disposed at vertices of a first regular hexagon, and another six of the twelve gas holes 5c are disposed at vertices of a second regular hexagon located inside the first regular hexagon.

In one embodiment, the substrate support 11 may include a plurality of pin holes 5d into which a plurality of lifter pins for the substrate W are inserted. The plurality of pin holes 5d are included in the surface structure of the electrostatic chuck 51. In the example shown in FIG. 4, the plurality of pin holes 5d are composed of three pin holes 5d. In one example, each of the plurality of pin holes 5d is composed of a through-hole of the electrostatic chuck 51 and a through-hole of the base 50 that communicate with each other. A lifter pin configured to be able to move the substrate W up and down is inserted into each of the plurality of pin holes 5d.

As illustrated in FIG. 4, the plurality of pin holes 5d may form a regular pattern centered on the center position 11c of the substrate support 11. In the example shown in FIG. 4, the plurality of pin holes 5d are disposed at vertices of a regular triangle centered on the center position 11c of the substrate support 11. In this case, the pattern of the plurality of pin holes 5d includes a triangle.

As described above, the plasma processing apparatus 1 is configured to perform substrate processing on the substrate W on the substrate support 11. In one example, the substrate support 11, the electrostatic chuck 51, and the substrate W are disk-shaped. The substrate processing may be an etching process or a process of forming a deposit on a surface of the substrate W (for example, a plasma CVD method). In the example shown in FIG. 6, a pattern of a deposit Wa formed on an upper surface of the substrate W by the substrate processing and a pattern of a deposit Wb formed on the lower surface of the substrate W by the substrate processing are shown. On the lower surface of the substrate W, the pattern of the deposit Wb has an inner periphery inside the edge of the substrate W.

The substrate W is transferred by the transfer module TM1 or TM2 to a transfer position on the substrate support 11. Then, in the plasma processing apparatus 1, substrate processing is performed on the substrate W on the electrostatic chuck 51. In one embodiment, the substrate W on which the substrate processing has been performed is transferred from the transfer position on the substrate support 11 to the substrate inspection module CM by the transfer module TM1 or TM2.

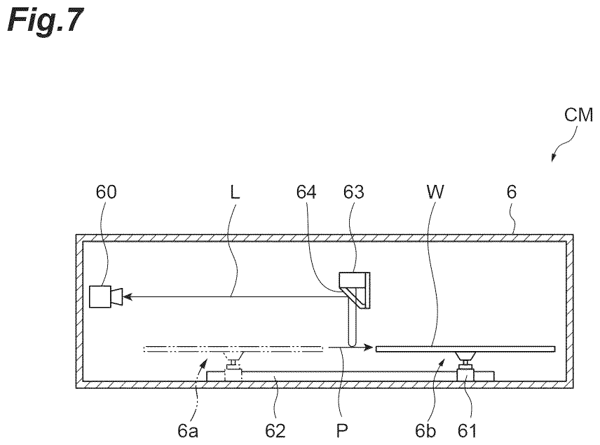

Hereinafter, refer to FIG. 7. FIG. 7 is a cross-sectional view of a substrate inspection module according to one example embodiment. In the example shown in FIG. 7, the substrate inspection module CM includes a housing 6. As shown in FIG. 7, the substrate inspection module CM may further include an imaging unit 60, a substrate chuck 61, a guide rail 62, a light source 63, and a half mirror 64. Each of the imaging unit 60, the substrate chuck 61, the guide rail 62, the light source 63, and the half mirror 64 is disposed in the housing 6.

The substrate chuck 61 is configured to support a substrate W placed thereon. The substrate chuck 61 is disposed on the guide rail 62. The guide rail 62 is configured to move the substrate chuck 61, which supports the substrate W, within the housing 6. In the example shown in FIG. 7, the guide rail 62 is configured to move the substrate W supported by the substrate chuck 61 along a transfer path P from a first position 6a to a second position 6b. The first position 6a is adjacent to one end of the guide rail 62. The second position 6b is adjacent to the other end of the guide rail 62. In one example, the distance between the first position 6a and the second position 6b is at least a diameter of the substrate W or more. The transfer path P of the substrate W may be along a straight line connecting one end of the guide rail 62 and the other end of the guide rail 62.

The imaging unit 60 has a field of view including the transfer path P of the substrate W. The imaging unit 60 is configured to acquire an image of the substrate W. In one embodiment, the imaging unit 60 may be a line scan camera. A direction of the transfer path P in the field of view of the imaging unit 60 and a long axis of the line scan camera are orthogonal to each other. In the example shown in FIG. 7, the imaging unit 60 acquires an image of the substrate W by acquiring light L, which is irradiated from the light source 63 and reflected by an upper surface of the substrate W, via the half mirror 64. The light source 63 and the half mirror 64 may be disposed above the transfer path P. The imaging unit 60 may be disposed to face the half mirror 64 in a horizontal direction. In one example, the light source 63 irradiates light L to the substrate W moving along the transfer path P from the first position 6a to the second position 6b. The light L reflected by the upper surface of the substrate W is reflected in the horizontal direction by the half mirror 64. The light L reflected in the horizontal direction by the half mirror 64 is received by the imaging unit 60.

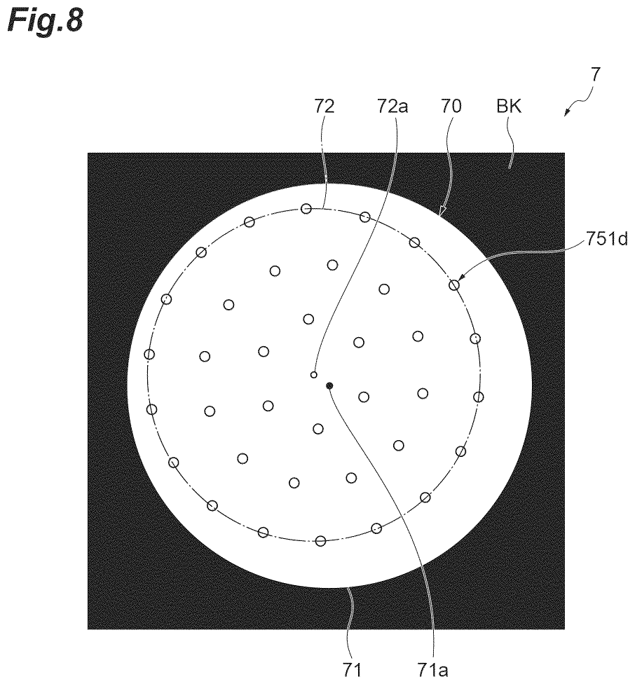

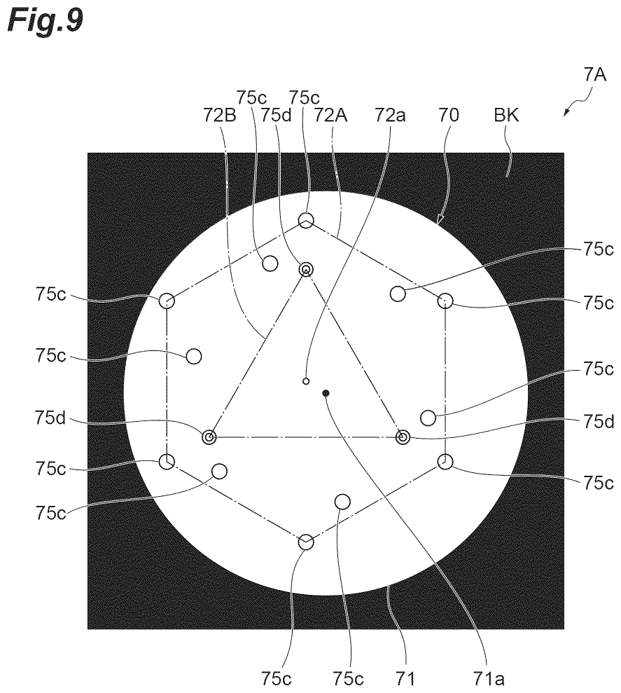

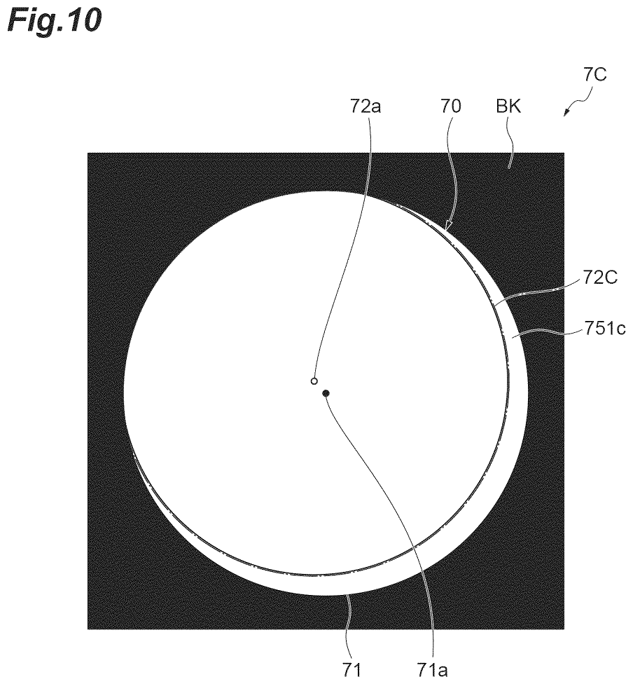

Hereinafter, refer to FIG. 8 to FIG. 10. FIG. 8 is a diagram schematically showing an image of a substrate according to one example embodiment on which substrate processing has been performed. FIG. 9 is a diagram schematically showing an image of a substrate according to another example embodiment on which substrate processing has been performed. FIG. 10 is a diagram schematically showing an image of a substrate according to still another example embodiment on which substrate processing has been performed.

The detector 2b1 is configured to detect a first characteristic pattern and a second characteristic pattern from an image of the substrate W on which substrate processing has been performed. In the example shown in FIG. 8, the detector 2b1 is configured to detect a first characteristic pattern 71 and a second characteristic pattern 72 from an image 7 of the substrate W on which substrate processing has been performed. Hereinafter, one example embodiment for detecting the first characteristic pattern 71 and the second characteristic pattern 72 from the image 7 will be described with reference to FIG. 8.

The first characteristic pattern 71 has a center that reflects a center position of the substrate W. In one embodiment, the first characteristic pattern 71 may reflect an edge 70 of the substrate W. In one example, the detector 2b1 detects the first characteristic pattern 71 from a difference in brightness and darkness between a background BK of the substrate W and the edge 70 in the image 7. In one embodiment, the detector 2b1 may detect the first characteristic pattern 71 by binarizing the image 7. By binarization, a pixel value of a region of the background BK of the substrate W in the image 7 is converted to a value different from a pixel value of a region of the substrate W in the image 7, so that the edge 70 of the substrate W can be detected as the first characteristic pattern 71 from the binarized image.

The second characteristic pattern 72 has a center that reflects a center position 11c of the substrate support 11 during the substrate processing. In one embodiment, the second characteristic pattern 72 may reflect a pattern of a surface structure of the electrostatic chuck 51. The second characteristic pattern 72 may have the center that reflects a center position of the electrostatic chuck 51 during the substrate processing. In one embodiment, the detector 2b1 may be configured to detect the second characteristic pattern 72 by a difference between the image 7 and an image obtained by a blurring process on the image 7. The blurring process is a process of averaging one pixel among a plurality of pixels constituting an image and a pixel adjacent to the one pixel.

In one embodiment, the second characteristic pattern 72 may reflect a pattern of the first protrusion 51c and/or the plurality of second protrusions 51d of the electrostatic chuck 51. In one embodiment, the second characteristic pattern 72 may reflect a pattern of a deposit Wa formed on an upper surface of the substrate W. In the substrate W, a temperature difference may occur between a first region located on the first protrusion 51c and/or the plurality of second protrusions 51d and a second region not located on the first protrusion 51c and/or the plurality of second protrusions 51d. A difference in an amount of the deposit Wa may occur between the deposit Wa formed on an upper surface of the first region and the deposit Wa formed on an upper surface of the second region, according to the temperature difference. Therefore, the second characteristic pattern 72 can reflect the difference in the amount of the deposit Wa. In the example shown in FIG. 8, the second characteristic pattern 72 reflects a pattern of the deposit Wa formed on the upper surface of the substrate W so as to reflect a pattern 751d of the plurality of second protrusions 51d.

The calculator 2b2 is configured to calculate a positional relationship between a position of the substrate support 11 and a position of the substrate W during the substrate processing, based on the first characteristic pattern and the second characteristic pattern. In the example shown in FIG. 8, the calculator 2b2 is configured to calculate a positional relationship between a position of the substrate support 11 and a position of the substrate W during the substrate processing, based on the first characteristic pattern 71 and the second characteristic pattern 72.

In one embodiment, the calculator 2b2 may be configured to calculate a positional relationship between a center position 11c of the substrate support 11 and a center position of the substrate W during the substrate processing, based on a first center position 71a identified from the first characteristic pattern 71 and a second center position 72a identified from the second characteristic pattern 72. In one example, since the first characteristic pattern 71 reflects the edge 70 of the substrate W, the center position of the substrate W is calculated as the first center position 71a identified from the first characteristic pattern 71.

In the example shown in FIG. 8, the second characteristic pattern 72 reflects the pattern 751d of the plurality of second protrusions 51d, and is arranged at substantially equal intervals along a circle having the center that reflects the center position 11c of the substrate support 11 during the substrate processing. Therefore, the center position 11c of the substrate support 11 during the substrate processing is calculated as a second center position 72a, which is a center position of the circle.

Hereinafter, another example embodiment for detecting the first characteristic pattern 71 and a second characteristic pattern 72A and/or a second characteristic pattern 72B from an image 7A will be described with reference to FIG. 9. In the following description, the other example embodiment will be described from the viewpoint of differences from the above example embodiment for detecting the first characteristic pattern 71 and the second characteristic pattern 72 from the image 7.

The second characteristic pattern 72A may reflect a pattern of the plurality of gas holes 5c of the electrostatic chuck 51. In the substrate W, a temperature difference may occur between a first region located on the plurality of gas holes 5c and a second region not located on the plurality of gas holes 5c. A difference in an amount of the deposit Wa may occur between the deposit Wa formed on an upper surface of the first region and the deposit Wa formed on an upper surface of the second region, according to the temperature difference. Therefore, the second characteristic pattern 72A can reflect the difference in the amount of the deposit Wa. In the example shown in FIG. 9, the second characteristic pattern 72A reflects a pattern of the deposit Wa formed on the upper surface of the substrate W so as to reflect a pattern 75c of the plurality of gas holes 5c.

In the example shown in FIG. 9, the second characteristic pattern 72A reflects the pattern 75c of the plurality of gas holes 5c, and is disposed at vertices of a hexagon having the center that reflects the center position 11c of the substrate support 11 during the substrate processing. In one example, this hexagon is a regular hexagon. The center position 11c of the substrate support 11 during the substrate processing is calculated as a second center position 72a, which is a center position of the hexagon.

In one embodiment, the second characteristic pattern 72B may reflect a pattern of the plurality of pin holes 5d of the electrostatic chuck 51. In the substrate W, a temperature difference may occur between a first region located on the plurality of pin holes 5d and a second region not located on the plurality of pin holes 5d. A difference in an amount of the deposit Wa may occur between the deposit Wa formed on an upper surface of the first region and the deposit Wa formed on an upper surface of the second region, according to the temperature difference. Therefore, the second characteristic pattern 72B can reflect the difference in the amount of the deposit Wa. In the example shown in FIG. 9, the second characteristic pattern 72B reflects a pattern of the deposit Wa formed on the upper surface of the substrate W so as to reflect a pattern 75d of the plurality of pin holes 5d.

In the example shown in FIG. 9, the second characteristic pattern 72B reflects the pattern 75d of the plurality of pin holes 5d, and is disposed at vertices of a triangle having the center that reflects the center position 11c of the substrate support 11 during the substrate processing. In one example, this triangle is a regular triangle. The center position 11c of the substrate support 11 during the substrate processing is calculated as a second center position 72a, which is a center position of the triangle.

Hereinafter, still another example embodiment for detecting the first characteristic pattern 71 and a second characteristic pattern 72C from an image 7C will be described with reference to FIG. 10. In the following description, the still another example embodiment will be described from the viewpoint of differences from the above example embodiment for detecting the first characteristic pattern 71 and the second characteristic pattern 72 from the image 7.

The second characteristic pattern 72C may reflect a pattern of the first protrusion 51c and/or the plurality of second protrusions 51d of the electrostatic chuck 51. In one embodiment, the second characteristic pattern 72C may reflect a pattern formed on an upper surface of the substrate W by an etching process, which is the substrate processing. In the substrate W, a temperature difference may occur between a first region located on the first protrusion 51c and/or the plurality of second protrusions 51d and a second region not located on the first protrusion 51c and/or the plurality of second protrusions 51d. A difference in an etching rate may occur between an etching rate of the first region and an etching rate of the second region, according to the temperature difference. Therefore, the second characteristic pattern 72C may reflect a difference in an amount of etching process. In the example shown in FIG. 10, the second characteristic pattern 72C reflects a pattern formed on the upper surface of the substrate W by the etching process so as to reflect a pattern 751c of the first protrusion 51c.

In the example shown in FIG. 10, the second characteristic pattern 72C reflects the pattern 751c of the first protrusion 51c, and has an annular shape having the center that reflects the center position 11c of the substrate support 11 during the substrate processing. The pattern 751c of the first protrusion 51c may have an annular shape along an outer edge of the substrate support surface 11a, and the second characteristic pattern 72C may reflect the annular shape. The center position 11c of the substrate support 11 during the substrate processing is calculated as a second center position 72a, which is a center position of the annular shape of the second characteristic pattern 72C. The center position 11c of the substrate support 11 during the substrate processing may be calculated from the second characteristic pattern 72C reflecting a pattern of the plurality of second protrusions 51d, instead of or in addition to the pattern of the first protrusion 51c.

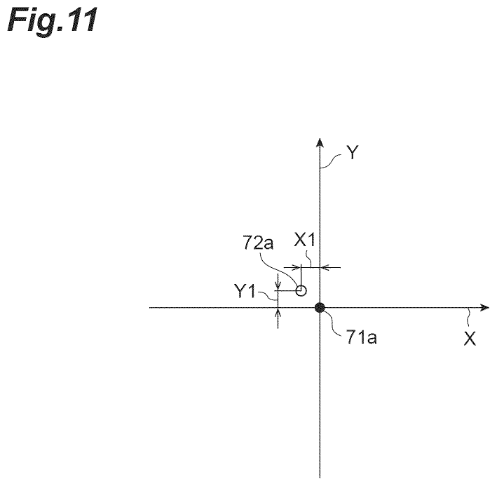

FIG. 11 is a diagram showing one example embodiment showing a positional relationship between a center position of a substrate and a center position of a pattern. The transfer controller CU is configured to correct a transfer position for the transfer modules TM1, TM2 based on a positional relationship between a position of the substrate support 11 and a position of the substrate W during the substrate processing. In one embodiment, the transfer controller CU may be configured to correct the transfer position for the transfer modules TM1, TM2 based on a positional relationship between a center position 11c of the substrate support 11 and a center position of the substrate W during the substrate processing. In one example, the transfer controller CU is configured to correct the transfer position for the transfer modules TM1, TM2 so that the center position 11c of the substrate support 11 during the substrate processing and the center position of the substrate W overlap.

The example shown in FIG. 11 indicates a position of a second center position 72a in an XY orthogonal coordinate system centered on a first center position 71a. In an X-axis direction, the second center position 72a is deviated by X1 with respect to the first center position 71a. In a Y-axis direction, the second center position 72a is deviated by Y1 with respect to the first center position 71a. In this case, the transfer controller CU may correct the transfer position on the substrate support 11 by X1 in the X-axis direction and by Y1 in the Y-axis direction.

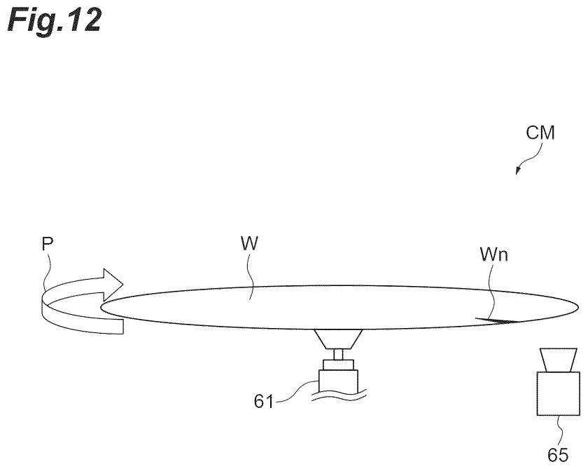

FIG. 12 is a diagram showing a configuration of an imaging unit according to another example embodiment. The substrate inspection module CM may include an imaging unit 65 (i.e., camera). The imaging unit 65 has a field of view including an edge of the substrate W. The imaging unit 65 is configured to acquire an image of the substrate W. In the example shown in FIG. 12, the imaging unit 65 is disposed below the substrate W supported by the substrate chuck 61.

The substrate chuck 61 is configured to rotate the substrate W supported thereon. In the example shown in FIG. 12, when viewed from above, the substrate chuck 61 is rotating the substrate W supported thereon in a clockwise direction. The imaging unit 65 may have a field of view capable of imaging a part of the edge of the substrate W. In one example, the imaging unit 65 may be a line scan camera. A longitudinal direction of the line scan camera is perpendicular to a tangent of the substrate W. In this case, the entire edge of the substrate W may be brought into the field of view of the imaging unit 65 as the substrate is rotated by the substrate chuck 61.

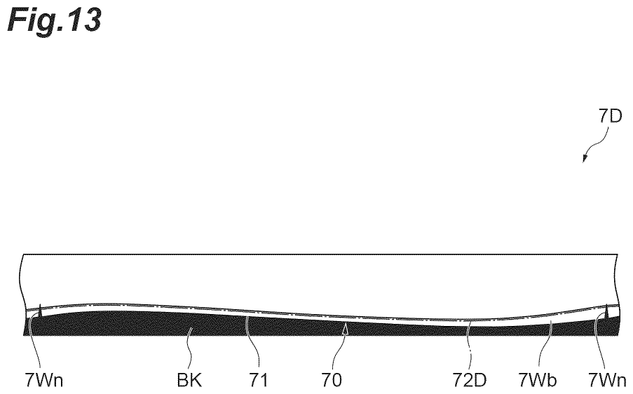

FIG. 13 is a diagram schematically showing an image of a substrate according to still another example embodiment to which substrate processing has been applied. An image 7D shown in FIG. 13 is an image acquired by the imaging unit 65 from the substrate W rotating on the substrate chuck 61. In the image 7D, an image of the substrate W is acquired in a strip shape. Hereinafter, still another example embodiment for detecting the first characteristic pattern 71 and a second characteristic pattern 72D from the image 7D will be described with reference to FIG. 13. In the following description, the still another example embodiment will be described from the viewpoint of differences from the above example embodiment for detecting the first characteristic pattern 71 and the second characteristic pattern 72 from the image 7.

In one embodiment, the second characteristic pattern 72D may reflect a pattern of a deposit Wb. The deposit Wb is formed on a lower surface of the substrate W by the substrate processing. As described above, the pattern of the deposit Wb has an inner periphery on the inner side with respect to an edge of the substrate W on the lower surface of the substrate W. This inner periphery may be reflected on the lower surface of the substrate W by an outer edge of the first protrusion 51c during the substrate processing. In one embodiment, the detector 2b1 may be configured to detect the second characteristic pattern 72D by a difference between the image 7D and an image of the substrate W before the substrate processing is performed.

The substrate W may have a cutout portion Wn at an edge of the substrate W. The cutout portion Wn may be, for example, a notch (a U-shaped, V-shaped, or the like groove). As shown in FIG. 13, the imaging unit 65 acquires an image 7Wn of the cutout portion Wn as a part of the image 7D. The imaging unit 65 acquires the image 7D over the entire circumference of the edge of the substrate W with reference to the image 7Wn of the cutout portion Wn.

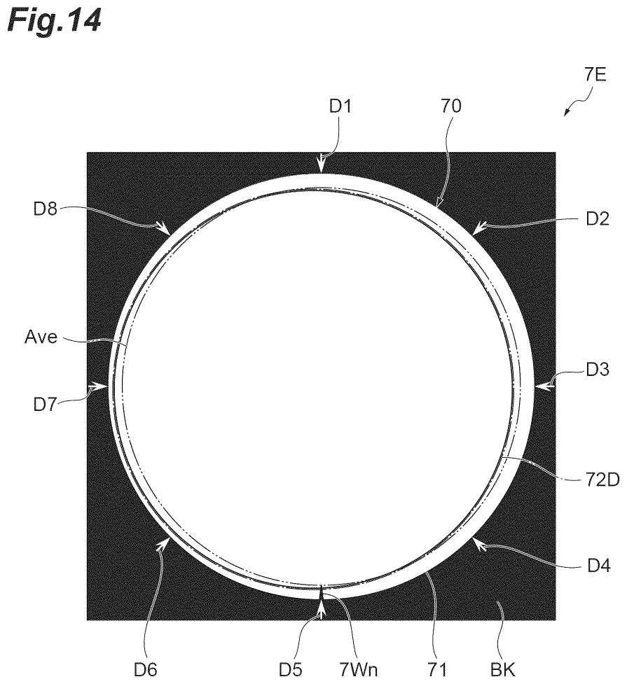

FIG. 14 is a diagram showing an example of a process of calculating a positional relationship between a position of a substrate and a position of a pattern. An image 7E shown in FIG. 14 is an image obtained by converting the image 7D so that the substrate W in the image 7D has a circular shape.

In one embodiment, the calculator 2b2 may be configured to obtain a distance between an inner periphery in the second characteristic pattern 72D and an edge 70 in the first characteristic pattern 71 in each of three or more radial directions at the edge 70 of the first characteristic pattern 71. The calculator 2b2 may be configured to calculate a positional relationship between a position of the substrate support 11 and a position of the substrate W during the substrate processing, from the distance in each of the three or more radial directions.

In the example shown in FIG. 14, the calculator 2b2 is configured to obtain a distance between an inner periphery in the second characteristic pattern 72D and an edge 70 in the first characteristic pattern 71 in each of eight radial directions at the edge 70. The eight radial directions are composed of a radial direction D1, a radial direction D2, a radial direction D3, a radial direction D4, a radial direction D5, a radial direction D6, a radial direction D7, and a radial direction D8. An angle between two adjacent radial directions among the eight radial directions D1 to D8 is 45 degrees. The radial direction D1 and the radial direction D5 are opposed by 180 degrees. The radial direction D5 is a position corresponding to the image 7Wn of the cutout portion Wn. The radial direction D2 and the radial direction D6 are opposed by 180 degrees. The radial direction D3 and the radial direction D7 are opposed by 180 degrees. The radial direction D4 and the radial direction D8 are opposed by 180 degrees.

In one embodiment, the calculator 2b2 may be configured to calculate an average distance between the inner periphery in the second characteristic pattern 72D and the edge 70 in the first characteristic pattern 71. In the example shown in FIG. 14, the calculator 2b2 may be configured to calculate the average distance between the inner periphery in the second characteristic pattern 72D and the edge 70 in the first characteristic pattern 71 from each of the radial direction D2, the radial direction D4, the radial direction D6, and the radial direction D8. The transfer controller CU may be configured to correct a transfer position for the transfer module based on the average distance.

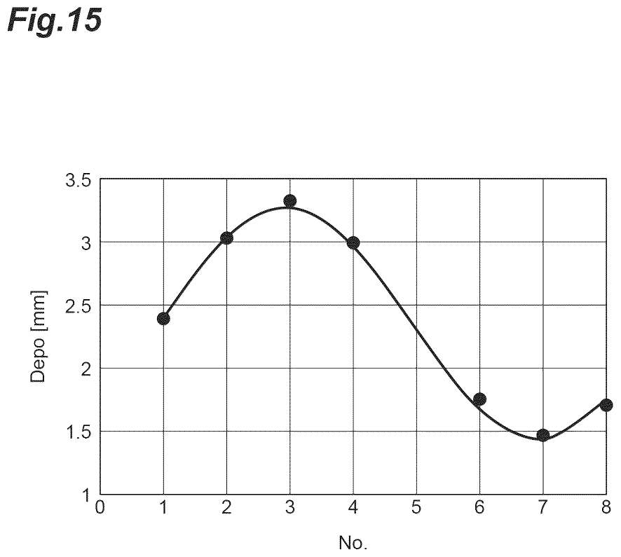

FIG. 15 is a diagram showing another example of a process of calculating a positional relationship between a position of a substrate and a position of a pattern. In one embodiment, the calculator 2b2 may be configured to calculate a distance between an inner periphery in the second characteristic pattern 72D and an edge 70 in the first characteristic pattern 71 in each of three or more radial directions. The calculator 2b2 may calculate a first angle and a second angle. The first angle is an angle between a first radial direction and a second radial direction different from the first radial direction among the three or more radial directions. The second angle is an angle between the second radial direction and a third radial direction different from the second radial direction. The calculator 2b2 may calculate a sine wave function based on the distance in each of the three or more radial directions, the first angle, and the second angle. The calculated sine wave function is configured to interpolate the distance between the inner periphery and the edge in a radial direction within the first angle and the distance between the inner periphery and the edge in a radial direction within the second angle. The calculator 2b2 may be configured to use the calculated sine wave function to correct the distance in each of the three or more radial directions.

In the example shown in FIG. 15, the calculator 2b2 is configured to calculate a distance between an inner periphery in the second characteristic pattern 72D and an edge 70 in the first characteristic pattern 71 in each of radial directions D1 to D4 and D6 to D8. No. 1 to No. 4 and No. 6 to No. 8 in FIG. 15 indicate the distance in each of the radial directions D1 to D4 and D6 to D8. The distance in the radial direction D5 is not measured because it interferes with the image 7Wn of the cutout portion Wn.

In the example shown in FIG. 15, an angle between two adjacent radial directions among the eight radial directions D1 to D8 is 45 degrees. As a result, the calculator 2b2 calculates a sine wave function based on the distance in each of the radial directions D1 to D4 and D6 to D8, and the angle of 45 degrees. In one example, the calculator 2b2 may calculate the sine wave function from the distance in each of the radial directions D1 to D4 and D6 to D8 and the angle of 45 degrees using a least squares method. The distance in each of the radial directions D1 to D4 and D6 to D8 can be corrected by the sine wave function. The calculator 2b2 may be configured to calculate a positional relationship between a position of the substrate support 11 and a position of the substrate W during the substrate processing, from the corrected distance and the angle of 45 degrees.

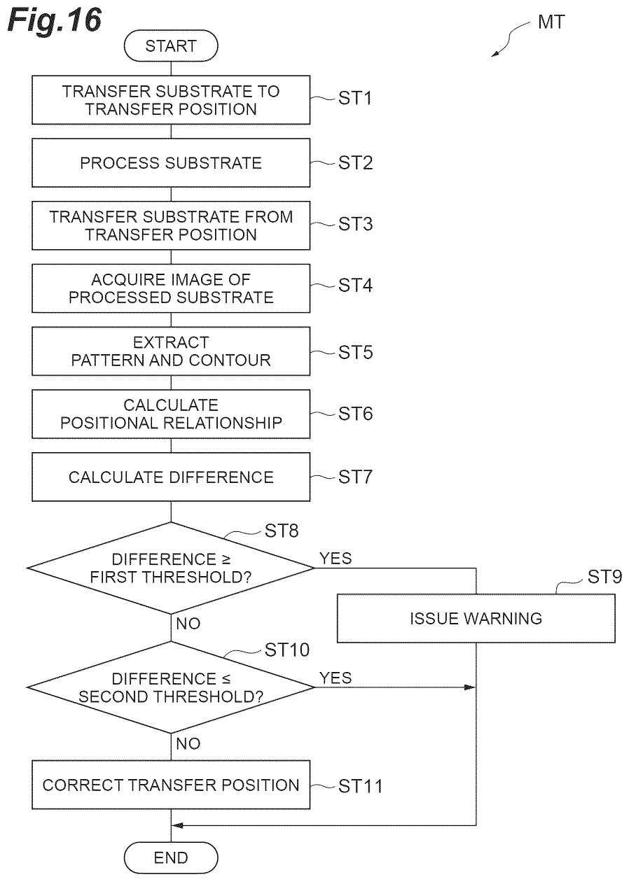

FIG. 16 is a flowchart showing a substrate processing method according to one example embodiment. Hereinafter, an example of executing a substrate processing method (hereinafter, referred to as “method MT”) will be described with reference to FIG. 16. The method MT is executed using the substrate processing system PS. Hereinafter, each configuration of the substrate processing system PS and control of each unit in the method MT will also be described. The method MT may be performed using a substrate processing system other than the substrate processing system PS.

The method MT starts at block ST1. In block ST1, a substrate W is transferred to a transfer position on a substrate support 11 disposed in a chamber 10. In one example, the transfer controller CU may be configured to control the transfer modules TM1, TM2 so that the substrate W is transferred to the transfer position on the substrate support 11 disposed in the chamber 10.

Block ST2 is performed after block ST1. In block ST2, substrate processing is performed on the substrate W on the substrate support 11. In one example, the substrate processing may be an etching process or a process of forming a deposit on a surface of the substrate W.

Block ST3 is performed after block ST2. In block ST2, the substrate W on which the substrate processing has been performed is transferred from the transfer position. In one example, the transfer controller CU may be configured to control the transfer modules TM1, TM2 so that the substrate W on which the substrate processing has been performed is transferred from the transfer position.

Block ST4 is performed after block ST3. In block ST4, an image of the substrate W being transferred along a transfer path P is acquired. In one embodiment, the imaging unit 60 may be configured to acquire an image of the substrate W being transferred along the transfer path P in the substrate inspection module CM.

Block ST5 is performed after block ST4. In block ST5, a first characteristic pattern 71 having the center that reflects a center position of the substrate W and a second characteristic pattern 72 having the center that reflects a center position 11c of the substrate support 11 during the substrate processing are detected from an image of the substrate W on which the substrate processing has been performed. In one example, the detector 2b1 may detect the first characteristic pattern 71 having the center at the center position of the substrate W from any one of images 7, 7A, 7C, and 7D of the substrate W on which the substrate processing has been performed. In one example, the detector 2b1 may be configured to detect at least one of second characteristic patterns 72, 72A, 72B, 72C, and 72D having the center that reflects the center position 11c of the substrate support 11 during the substrate processing from the image of the substrate W on which the substrate processing has been performed.

Block ST6 is performed after block ST5. In block ST6, a positional relationship between a position of the substrate support 11 and a position of the substrate W during the substrate processing is calculated based on the first characteristic pattern 71 and the second characteristic pattern 72. In one example, the calculator 2b2 may be configured to calculate a positional relationship between a position of the substrate support 11 and a position of the substrate W during the substrate processing, based on the first characteristic pattern 71 and at least one of the second characteristic patterns 72, 72A, 72B, 72C, and 72D. In one embodiment, in block ST6, a positional relationship between a first center position 71a identified from the first characteristic pattern 71 and a second center position 72a identified from any of the second characteristic patterns 72, 72A, 72B, 72C, and 72D may be calculated.

In one embodiment, block ST7, block ST8, block ST9, and block ST10 may be executed. Block ST7 is performed after block ST6. In block ST7, a difference between a position of the substrate support 11 and a position of the substrate W during the substrate processing (hereinafter, referred to as “positional difference”) is calculated. In block ST8, it is determined whether the positional difference is greater than or not less than a first threshold value. When it is determined that the positional difference is greater than or not less than the first threshold value, the transfer modules TM1, TM2 are controlled not to transfer the substrate W to the transfer position. The positional difference may be a difference between a center position 11c of the substrate support 11 and a center position of the substrate W during the substrate processing. In one example shown in FIG. 11, the positional difference may be a square root of a sum of a square of X1 and a square of Y1.

In one example, the transfer controller CU may be configured to determine whether the positional difference is greater than or not less than the first threshold value. The transfer controller CU may be configured to control the transfer modules TM1, TM2 not to transfer the substrate W to the transfer position when the positional difference is greater than or not less than the first threshold value.

In one embodiment, when it is determined that the positional difference is greater than or not less than the first threshold value, block ST9 may be subsequently executed. In block ST9, a warning is issued. In one example, the transfer controller CU may issue a warning indicating that the transfer of the substrate W to the transfer position is stopped because the positional difference is greater than or not less than the first threshold value. After block ST9, the method MT may end.

In one embodiment, when it is determined that the positional difference is not greater than or less than the first threshold value, block ST10 may be subsequently executed. In block ST10, it is determined whether the positional difference is smaller than or not greater than a second threshold value. When the positional difference is smaller than or not greater than the second threshold value, the transfer module is controlled to transfer the substrate W to the transfer position without correcting the transfer position, and then the method MT may end. In one example, the transfer controller CU may be configured to control the transfer modules TM1, TM2 to transfer the substrate W to the transfer position without correcting the transfer position when the positional difference is smaller than or not greater than the second threshold value.

In one embodiment, when it is determined that the positional difference is not smaller than or greater than the second threshold value, block ST11 may be subsequently executed. In block ST11, the transfer position is corrected based on the positional relationship. The transfer modules TM1, TM2 are controlled to transfer the substrate W to the corrected transfer position, and then the method MT may end. In one example, the transfer controller CU may be configured to correct the transfer position based on the positional relationship between the position of the substrate support 11 and the position of the substrate W during the substrate processing.

When a plurality of substrates W are to be processed, the method MT may be executed for some of the plurality of substrates W. For example, the method MT may be executed each time a predetermined number of substrates W or two or more substrates W are continuously processed. The correction of the transfer position may be applied to the substrate W to be processed after the method MT is executed. In the method MT, the substrate W may be a dummy substrate. For example, the method MT may be executed for a dummy substrate each time a predetermined number of substrates W or two or more substrates W are continuously processed. The correction of the transfer position can be applied to the substrate W to be processed after the method MT is executed for the dummy substrate. The method MT may be executed for a dummy substrate to check or correct the transfer position in a setup of the substrate processing system PS or in maintenance of the substrate processing system PS.

Although various example embodiments have been described above, various additions, omissions, substitutions, and changes may be made without being limited to the example embodiments described above. Further, it is possible to form other embodiments by combining elements in different embodiments.

The substrate processing system PS may not include the substrate inspection module CM. The imaging unit may not be included in the substrate inspection module CM. The imaging unit only needs to be disposed so that a transfer path of the substrate W is included in the field of view. The imaging unit may be included in any of the load ports LP1 to LP4, the aligner AN, the load lock modules LL1, LL2, and the storage SR. The imaging unit may be disposed in the chamber of the loader module LM. The imaging unit may be disposed in the chamber of the transfer module TM1, or may be disposed in the chamber of the transfer module TM2.

The second characteristic pattern 72 illustrated in FIG. 8 may reflect a pattern of the plurality of second protrusions 51d of the electrostatic chuck 51, and may reflect a pattern formed on an upper surface of the substrate W by an etching process, which is the substrate processing. The second characteristic pattern 72A illustrated in FIG. 9 may reflect a pattern of the plurality of gas holes 5c of the electrostatic chuck 51, and may reflect a pattern formed on an upper surface of the substrate W by an etching process, which is the substrate processing. The second characteristic pattern 72B illustrated in FIG. 9 may reflect a pattern of the plurality of pin holes 5d of the electrostatic chuck 51, and may reflect a pattern formed on an upper surface of the substrate W by an etching process, which is the substrate processing. The second characteristic pattern 72C illustrated in FIG. 10 may reflect a pattern of the first protrusion 51c of the electrostatic chuck 51, and may reflect a pattern of a deposit Wa formed on an upper surface of the substrate W.

Here, various example embodiments included in the present disclosure are described in the following [E1] to [E20].

### [E1]

A substrate processing system, comprising:
a process module having a chamber and a substrate support disposed in the chamber, the process module performing substrate processing on a substrate on the substrate support;
a transfer module including a transfer robot transferring the substrate to a transfer position on the substrate support;
a camera having a field of view including a transfer path of the substrate, the camera acquiring an image of the substrate;
processing circuitry including:
   a detector configured to detect, from an image of the substrate on which the substrate processing has been performed, a first characteristic pattern having a center that reflects a center position of the substrate, and a second characteristic pattern having a center that reflects a center position of the substrate support during the substrate processing;
   a calculator configured to calculate a positional relationship between a position of the substrate support and a position of the substrate during the substrate processing, based on the first characteristic pattern and the second characteristic pattern; and
transfer controller circuitry configured to correct the transfer position for the transfer module based on the positional relationship.

### [E2]

The substrate processing system according to E 1, wherein
the calculator is configured to calculate a positional relationship between the center position of the substrate support and the center position of the substrate during the substrate processing, based on a first center position identified from the first characteristic pattern and a second center position identified from the second characteristic pattern.

### [E3]

The substrate processing system according to E1 or E2, wherein the substrate support includes
an electrostatic chuck, and the second characteristic pattern reflects a pattern of a surface structure of the electrostatic chuck.

[E4]

The substrate processing system according to E 3, wherein the electrostatic chuck includes:
a first protrusion having an annular shape and having an upper surface that forms a substrate support surface; and
a plurality of second protrusions, each of which has an upper surface that forms the substrate support surface and is disposed inside the first protrusion, and
the second characteristic pattern reflects a pattern of the first protrusion and/or the plurality of second protrusions.

### [E5]

The substrate processing system according to E 4, wherein
the second characteristic pattern reflects a pattern formed on an upper surface of the substrate by an etching process, which is the substrate processing.

### [E6]

The substrate processing system according to any one of E3 to E5, wherein the substrate support includes
a plurality of gas holes communicating with a gap between the substrate and the electrostatic chuck, and
the second characteristic pattern reflects a pattern of the plurality of gas holes.

### [E7]

The substrate processing system according to any one of E1 to E6, wherein the substrate support includes
a plurality of pin holes into which a plurality of lifter pins for the substrate are inserted, and
the second characteristic pattern reflects a pattern of the plurality of pin holes.

### [E8]

The substrate processing system according to any one of E1 to E7, wherein
the second characteristic pattern reflects a pattern of a deposit formed on an upper surface of the substrate by the substrate processing.

### [E9]

The substrate processing system according to any one of E1 to E8, wherein
the second characteristic pattern reflects a pattern of a deposit formed on a lower surface of the substrate by the substrate processing, and
the pattern of the deposit has an inner periphery on an inner side with respect to an edge of the substrate on the lower surface of the substrate.

### [E10]

The substrate processing system according to E9, wherein
the first characteristic pattern is a pattern reflecting the edge of the substrate, and
the calculator is configured to obtain a distance between an inner periphery in the second characteristic pattern and the edge in the first characteristic pattern in each of three or more radial directions at the edge of the first characteristic pattern, and to calculate the positional relationship from the distance in each of the three or more radial directions.

[E11]

The substrate processing system according to E10,
wherein the calculator is configured to:
calculate a sine wave function based on the distance in each of the three or more radial directions, a first angle between a first radial direction and a second radial direction different from the first radial direction among the three or more radial directions, and a second angle between the second radial direction and a third radial direction different from the second radial direction,
wherein the calculated sine wave function is configured to interpolate the distance between the inner periphery and the edge in a radial direction within the first angle and the distance between the inner periphery and the edge in a radial direction within the second angle; and
use the calculated sine wave function to correct the distance in each of the three or more radial directions.

### [E12]

The substrate processing system according to any one of E1 to E11, wherein
the transfer controller circuitry is configured to control the transfer module not to transfer the substrate to the transfer position when a difference between a position of the substrate support and a position of the substrate during the substrate processing is greater than or not less than a first threshold value.

### [E13]

The substrate processing system according to E12, wherein
the transfer controller circuitry is configured to issue a warning when the difference is greater than or not less than the first threshold value.

### [E14]

The substrate processing system according to any one of E1 to E13, wherein
the transfer controller circuitry is configured to control the transfer module to transfer the substrate to the transfer position without correcting the transfer position when a difference between a position of the substrate support and a position of the substrate during the substrate processing is smaller than or not greater than a second threshold value.

### [E15]

The substrate processing system according to any one of E1 to E14, wherein
the transfer controller circuitry is configured to correct the transfer position based on the positional relationship and to control the transfer module to transfer the substrate to the corrected transfer position when a difference between a position of the substrate support and a position of the substrate during the substrate processing is smaller than or not greater than a first threshold value and is greater than or not less than a second threshold value.

### [E16]

The substrate processing system according to any one of E1 to E15, wherein
the detector is configured to detect the first characteristic pattern by binarizing the image.

### [E17]

The substrate processing system according to any one of E1 to E16, wherein
the detector is configured to detect the second characteristic pattern by a difference between the image and an image obtained by a blurring process on the image.

### [E18]

A substrate processing method, comprising:
transferring a substrate to a transfer position on a substrate support disposed in a chamber;
performing substrate processing on the substrate on the substrate support;
transferring the substrate, on which the substrate processing has been performed, from the transfer position;
acquiring an image of the substrate being transferred along a transfer path;
detecting, from an image of the substrate on which the substrate processing has been performed, a first characteristic pattern having its center that reflects a center position of the substrate, and a second characteristic pattern having its center that reflects a center position of the substrate support during the substrate processing;
calculating a positional relationship between a position of the substrate support and a position of the substrate during the substrate processing, based on the first characteristic pattern and the second characteristic pattern; and
correcting the transfer position based on the positional relationship.

### [E19]

A non-transitory computer-readable storage medium storing a program that, when executed by a computer of a substrate processing system, causes the substrate processing system to perform the substrate processing method according to E18.

### [E20]

The substrate processing method according to E18, wherein
the positional relationship is a positional difference between the position of the substrate support and the position of the substrate during substrate processing, and
in response to the positional difference being greater than a threshold, correcting the transfer position.

It is to be understood that not all aspects, advantages and features described herein may necessarily be achieved by, or included in, any one particular example. Indeed, having described and illustrated various examples herein, it should be apparent that other examples may be modified in arrangement and detail. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

What is claimed is:

1. A substrate processing system, comprising:
a process module having a chamber and a substrate support disposed in the chamber, the process module performing substrate processing on a substrate on the substrate support;
a transfer module including a transfer robot transferring the substrate to a transfer position on the substrate support;
a camera having a field of view including a transfer path of the substrate, the camera acquiring an image of the substrate;
processing circuitry including:
a detector configured to detect, from an image of the substrate on which the substrate processing has been performed, a first characteristic pattern having a center that reflects a center position of the substrate, and a second characteristic pattern having a center that reflects a center position of the substrate support during the substrate processing;
a calculator configured to calculate a positional relationship between a position of the substrate support and a position of the substrate during the substrate processing, based on the first characteristic pattern and the second characteristic pattern; and
transfer controller circuitry configured to correct the transfer position for the transfer module based on the positional relationship.

2. The substrate processing system according to claim 1, wherein
the calculator is configured to calculate a positional relationship between the center position of the substrate support and the center position of the substrate during the substrate processing, based on a first center position identified from the first characteristic pattern and a second center position identified from the second characteristic pattern.

3. The substrate processing system according to claim 2, wherein the substrate support includes
an electrostatic chuck, and
the second characteristic pattern reflects a pattern of a surface structure of the electrostatic chuck.

4. The substrate processing system according to claim 3, wherein the electrostatic chuck includes:
a first protrusion having an annular shape and having an upper surface that forms a substrate support surface; and
a plurality of second protrusions, each of which has an upper surface that forms the substrate support surface and is disposed inside the first protrusion, and
the second characteristic pattern reflects a pattern of the first protrusion and/or the plurality of second protrusions.

5. The substrate processing system according to claim 4, wherein
the second characteristic pattern reflects a pattern formed on an upper surface of the substrate by an etching process, which is the substrate processing.

6. The substrate processing system according to claim 3, wherein the substrate support includes
a plurality of gas holes communicating with a gap between the substrate and the electrostatic chuck, and
the second characteristic pattern reflects a pattern of the plurality of gas holes.

7. The substrate processing system according to claim 1, wherein the substrate support includes
a plurality of pin holes into which a plurality of lifter pins for the substrate are inserted, and
the second characteristic pattern reflects a pattern of the plurality of pin holes.

8. The substrate processing system according to claim 6, wherein
the second characteristic pattern reflects a pattern of a deposit formed on an upper surface of the substrate by the substrate processing.

9. The substrate processing system according to claim 1, wherein
the second characteristic pattern reflects a pattern of a deposit formed on a lower surface of the substrate by the substrate processing, and
the pattern of the deposit has an inner periphery on an inner side with respect to an edge of the substrate on the lower surface of the substrate.

10. The substrate processing system according to claim 9, wherein
the first characteristic pattern is a pattern reflecting the edge of the substrate, and
the calculator is configured to obtain a distance between an inner periphery in the second characteristic pattern and the edge in the first characteristic pattern in each of three or more radial directions at the edge of the first characteristic pattern, and to calculate the positional relationship from the distance in each of the three or more radial directions.

11. The substrate processing system according to claim 10, wherein the calculator is configured to:
calculate a sine wave function based on the distance in each of the three or more radial directions, a first angle between a first radial direction and a second radial direction different from the first radial direction among the three or more radial directions, and a second angle between the second radial direction and a third radial direction different from the second radial direction,
wherein the calculated sine wave function is configured to interpolate the distance between the inner periphery and the edge in a radial direction within the first angle and the distance between the inner periphery and the edge in a radial direction within the second angle; and
use the calculated sine wave function to correct the distance in each of the three or more radial directions.

12. The substrate processing system according to claim 1, wherein
the transfer controller circuitry is configured to control the transfer module not to transfer the substrate to the transfer position when a difference between a position of the substrate support and a position of the substrate during the substrate processing is greater than or not less than a first threshold value.

13. The substrate processing system according to claim 12, wherein
the transfer controller circuitry is configured to issue a warning when the difference is greater than or not less than the first threshold value.

14. The substrate processing system according to claim 1, wherein
the transfer controller circuitry is configured to control the transfer module to transfer the substrate to the transfer position without correcting the transfer position when a difference between a position of the substrate support and a position of the substrate during the substrate processing is smaller than or not greater than a second threshold value.

15. The substrate processing system according to claim 1, wherein
the transfer controller circuitry is configured to correct the transfer position based on the positional relationship and to control the transfer module to transfer the substrate to the corrected transfer position when a difference between a position of the substrate support and a position of the substrate during the substrate processing is smaller than or not greater than a first threshold value and is greater than or not less than a second threshold value.

16. The substrate processing system according to claim 1, wherein
the detector is configured to detect the first characteristic pattern by binarizing the image.

17. The substrate processing system according to claim 1, wherein
the detector is configured to detect the second characteristic pattern by a difference between the image and an image obtained by a blurring process on the image.

18. A substrate processing method, comprising:
transferring a substrate to a transfer position on a substrate support disposed in a chamber;
performing substrate processing on the substrate on the substrate support;
transferring the substrate, on which the substrate processing has been performed, from the transfer position;
acquiring an image of the substrate being transferred along a transfer path;
detecting, from an image of the substrate on which the substrate processing has been performed, a first characteristic pattern having its center that reflects a center position of the substrate, and a second characteristic pattern having its center that reflects a center position of the substrate support during the substrate processing;
calculating a positional relationship between a position of the substrate support and a position of the substrate during the substrate processing, based on the first characteristic pattern and the second characteristic pattern; and
correcting the transfer position based on the positional relationship.

19. A non-transitory computer-readable storage medium storing a program that, when executed by a computer of a substrate processing system, causes the substrate processing system to perform the substrate processing method according to claim 18.

20. The substrate processing method according to claim 18, wherein
the positional relationship is a positional difference between the position of the substrate support and the position of the substrate during substrate processing, and
in response to the positional difference being greater than a threshold, correcting the transfer position.
